(19) United States
(12) Patent Application Publication
(10) Pub. No.: US 2025/0336775 A1
(43) Pub. Date: Oct. 30, 2025

(54) SEMICONDUCTOR PACKAGES AND ASSOCIATED MANUFACTURING METHODS

(71) Applicant: Infineon Technologies AG, Neubiberg (DE)

(72) Inventors: Stefan SCHWAB, Regensburg (DE); Dexter Inciong REYNOSO, Singapore (SG); Ganesh VETRIVEL PERIASAMY, Singapore (SG)

(73) Assignee: Infineon Technologies AG, Neubiberg (DE)

(21) Appl. No.: 19/093,600

(22) Filed: Mar. 28, 2025

(30) Foreign Application Priority Data
Apr. 24, 2024 (DE) 10 2024 111 531.9

(51) Int. Cl. H01L 23/495; H01L 21/56; H01L 25/18

(52) U.S. Cl. CPC H01L 23/49513; H01L 21/561; H01L 23/4951; H01L 23/4952; H01L 23/49555; H01L 23/49582; H01L 25/18

(57) ABSTRACT

A semiconductor package and method is disclosed. In one example, the method includes providing a first leadframe panel including multiple first leadframes, wherein the first leadframes include multiple first diepads plated with a first plating material. The method further includes providing a second leadframe panel separate from the first leadframe panel and including multiple second leadframes, wherein the second leadframes include multiple second diepads plated with a second plating material different from the first plating material. The method further includes mechanically connecting the first leadframe panel and the second leadframe panel to form a combined leadframe panel. The method further includes mounting a plurality of first semiconductor chips of a first type on the first leadframe panel, and mounting a plurality of second semiconductor chips of a second type different from the first type on the second leadframe panel.

### CROSS-REFERENCE TO RELATED APPLICATION

This Utility Patent application claims priority to German Patent Application No. 10 2024 111 531.9 filed Apr. 24, 2024, which is incorporated herein by reference.

### TECHNICAL FIELD

The present disclosure relates to semiconductor packages and associated manufacturing methods.

### BACKGROUND

Semiconductor packages may include different types of semiconductor chips that may be mounted on one or more package leadframes. The leadframes can be of different designs and may be manufactured from different materials. An integration of various semiconductor chips in a same package can be challenging and may in some cases require different leadframe surfaces for a proper mounting of the semiconductor chips. This may require expensive plating technologies strongly increasing the overall package costs. In view of the above, it may be desirable to provide simple and cost efficient methods for the fabrication of advantageous semiconductor packages.

### SUMMARY

An aspect of the present disclosure relates to a method. The method comprises a step of providing a first leadframe panel comprising multiple first leadframes, wherein the first leadframes comprise multiple first diepads plated with a first plating material. The method further comprises a step of providing a second leadframe panel separate from the first leadframe panel and comprising multiple second leadframes, wherein the second leadframes comprise multiple second diepads plated with a second plating material different from the first plating material. The method further comprises a step of mechanically connecting the first leadframe panel and the second leadframe panel to form a combined leadframe panel. The method further comprises a step of mounting a plurality of first semiconductor chips of a first type on the first leadframe panel. The method further comprises a step of mounting a plurality of second semiconductor chips of a second type different from the first type on the second leadframe panel.

A further aspect of the present disclosure relates to a semiconductor package. The semiconductor package comprises a first leadframe comprising a first diepad plated with a first plating material and a second leadframe comprising a second diepad plated with a second plating material different from the first plating material. The semiconductor package further comprises a first semiconductor chip of a first type mounted on the first leadframe and a second semiconductor chip of a second type different from the first type mounted on the second leadframe.

### BRIEF DESCRIPTION OF THE DRAWINGS

Methods and devices in accordance with the disclosure are described in more detail below based on the drawings. The elements of the drawings are not necessarily to scale relative to each other. Similar reference numerals may designate corresponding similar parts. The technical features of the various illustrated examples may be combined unless they exclude each other and/or can be selectively omitted if not described to be necessarily required.

FIG. 1 illustrates a flowchart of a method in accordance with the disclosure.

FIG. 2 includes FIGS. 2A to 2H schematically illustrating a method in accordance with the disclosure.

FIG. 3 includes FIGS. 3A to 3C schematically illustrating leadframe panels that may be used in a method in accordance with the disclosure.

FIG. 4 schematically illustrates a cross-sectional side view of a semiconductor package 400 in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

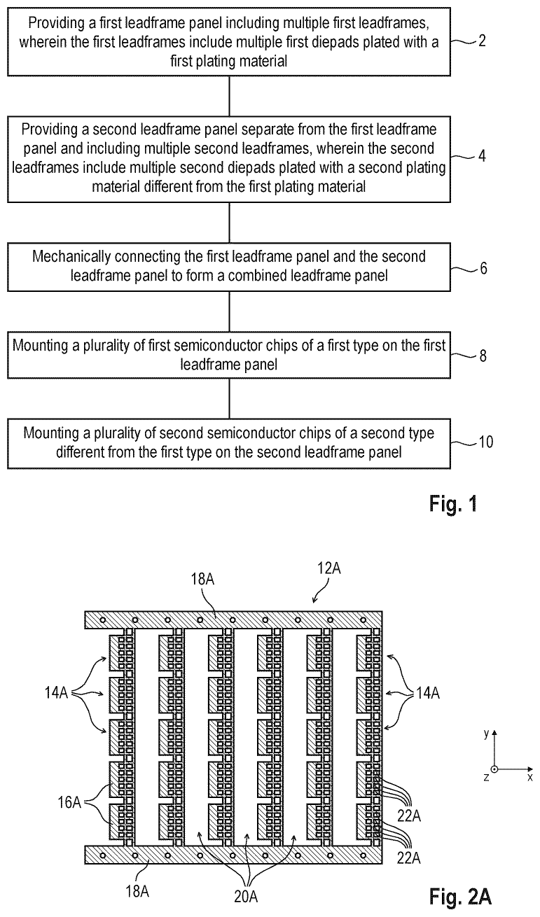

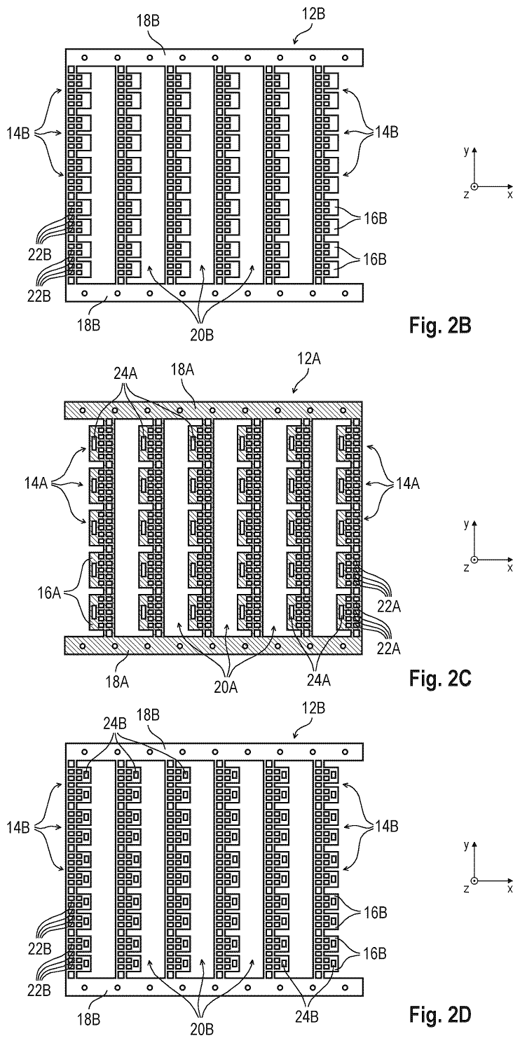

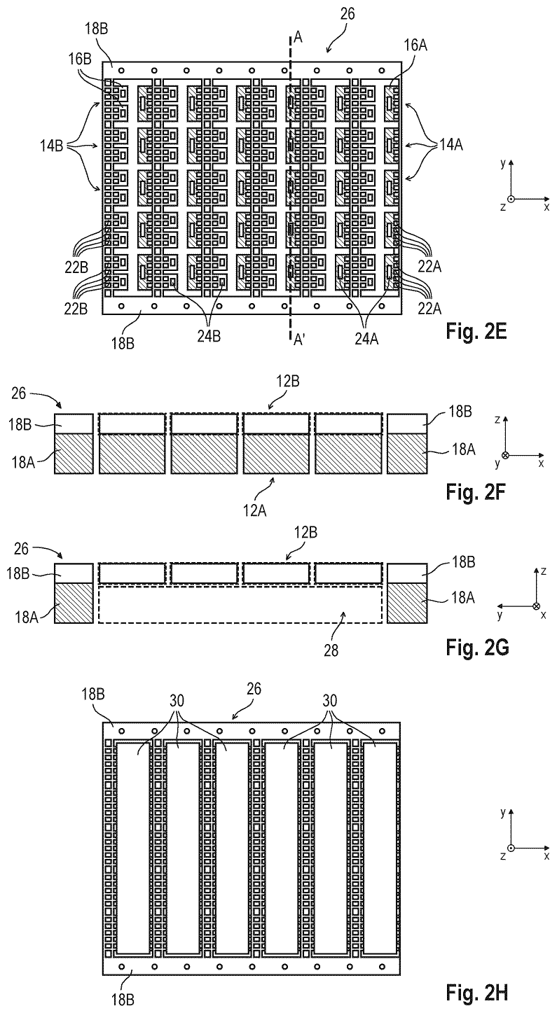

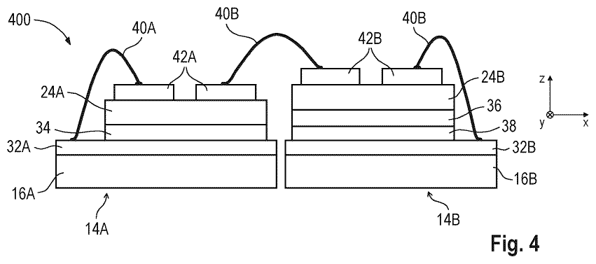

Referring now to FIG. 1, a flowchart of a method in accordance with the disclosure is illustrated. The method is described in a general manner in order to qualitatively specify aspects of the disclosure. The method may be used for manufacturing semiconductor packages in accordance with the disclosure, such as the semiconductor package 400 of FIG. 4 described later on. It is to be understood that the method may include further aspects. For example, the method may be extended by any of the aspects described in connection with the method of FIG. 2 or any other example described herein.

In a step 2, a first leadframe panel including multiple first leadframes may be provided. The first leadframes may include multiple first diepads plated with a first plating material. In a step 4, a second leadframe panel separate from the first leadframe panel and including multiple second leadframes may be provided. The second leadframes may include multiple second diepads plated with a second plating material different from the first plating material. In a step 6, the first leadframe panel and the second leadframe panel may be mechanically connected to form a combined leadframe panel. In a step 8, a plurality of first semiconductor chips of a first type may be mounted on the first leadframe panel. In a step 10, a plurality of second semiconductor chips of a second type different from the first type may be mounted on the second leadframe panel.

It is to be noted that the above steps do not necessarily have to be carried out in the given order, but may be at least partially swapped in their order if technically possible. As an example, the steps 8 and 10 of mounting the first and second semiconductor chips on the first and second leadframe panels may be performed before or after the step 6 of mechanically connecting the first and second leadframe panels to form the combined leadframe panel.

Referring now to FIGS. 2A to 2H, a further method in accordance with the disclosure is described. The method of FIG. 2 may be seen, at least in parts, as a more detailed version of the previously described method of FIG. 1. For example, the method of FIG. 2 may be used for manufacturing the semiconductor package 400 of FIG. 4 described later on.

In FIG. 2A, a first leadframe panel 12A including multiple individual first leadframes 14A may be provided. For example, the step of FIG. 2A may correspond to the step 2 of FIG. 1. The first leadframes 14A may include multiple first diepads 16A. In the illustrated example, the first leadframe panel 12A may include a first peripheral frame 18A, wherein multiple rows of the first diepads 16A may be connected to opposite sides of the first peripheral frame 18A and separated by first gaps 20A. For example, each row of first diepads 16A may extend in the y-direction. The number of first diepads 16A per individual leadframe 14A may depend on the type of semiconductor package that is to be manufactured. In the shown case, each individual leadframe 14A may include a single first diepad 16A. However, in other cases, an individual leadframe 14A may include two or even more first diepads 16A.

It is to be noted that the method of FIG. 2 may correspond to a batch process in which multiple leadframes and semiconductor chips may be processed in a single batch, as opposed to individually processing each leadframe and semiconductor chip separately. Therefore, the first leadframe panel 12A may include a large number of individual leadframes 14A, for example dozens to hundreds. In a non-limiting and purely illustrative example, the first leadframe panel 12A may have 25 rows of 5 individual first leadframes 14A each, i.e. a total number of 125 individual first leadframes 14A.

The first diepads 16A may be plated with a first plating material which may, for example, depend on a type of the semiconductor chips that are to be mounted on the first diepads 16A and/or a material of electrical connection elements that are to be connected to the first diepads 16A. For example, an electrical connection element may include or may correspond to at least one of a wire, a ribbon, a clip, or the like. For the sake of simplicity, this description may particularly refer to wires as electrical connection elements. However, it is to be understood, that the wires described herein in connection with a specific example may be replaced by electrical connection elements of a different type, such as e.g. ribbons, clips, or the like. Stated differently, examples described herein are not limited to electrical connection elements in form of wires. For example, the first plating material may include or may correspond to at least one of Ni, NiP, NiNiP, Cu or Ag. In one case, the first diepads 16A may be fully plated with the first plating material. In further cases, only a part of a respective first diepad 16A may be plated with the first plating material, while another part of the diepad may remain non-plated.

The first leadframes 14A may further include multiple first leads (or pins or lead fingers) 22A which may be mechanically and/or electrically connected to an associated first diepad 16A or not. The number of first leads 22A per individual first leadframe 14A may depend on the type of semiconductor package that is to be manufactured. In the shown case, each individual first leadframe 14A may include multiple first leads 22A arranged to the right of a respective first diepad 16A. However, in other cases, a number and arrangement of the first leads 22A for an individual first leadframe 14A may differ.

The first leads 22A may be plated with a third plating material (note that a second plating material will be specified later on in connection with FIG. 2B). The third plating material may, for example, depend on a material of the wires that may be connected to the first leads 22A. For example, the third plating material may include or correspond to at least one of Ni, NiP, NiNiP, Cu or Ag. In one example, the third plating material on the first leads 22A may be different from the first plating material on the first diepads 16A. In a further example, the first plating material and the third plating material may be the same.

The first leadframe panel 12A may include a core onto which the first plating material of the first diepads 14A and/or the third plating material of the first leads 22A may have been deposited. The core of the first leadframe panel 12A may include a first core material. For example, the first core material may include or may be made of Cu or a Cu-alloy.

In FIG. 2B, a second leadframe panel 12B including multiple individual second leadframes 14B may be provided. For example, the step of FIG. 2B may correspond to the step 4 of FIG. 1. The second leadframes 14B may include multiple second diepads 16B. In the illustrated example, the second leadframe panel 12B may include a second peripheral frame 18B, wherein multiple rows of the second diepads 16B may be connected to opposite sides of the second peripheral frame 18B and separated by second gaps 20B. For example, each row of second diepads 16B may extend in the y-direction. The number of second diepads 16B per individual second leadframe 14B may depend on the type of semiconductor package that is to be manufactured. In the shown case, each individual second leadframe 14B may include two second diepads 16B. However, in other cases, an individual second leadframe 14B may include only one or even more than two second diepads 16B.

The second diepads 16B may be plated with a second plating material which may, for example, depend on a type of the semiconductor chips that are to be mounted on the second diepads 16B and/or a material of the wires that are to be connected to the second diepads 16B. For example, the second plating material may include at least one of Cu or Ag. Additionally, or alternatively, the second leadframes 14B may be pre-plated frames (PPF) or micro pre-plated frames (uPPF). In one case, the second diepads 16B may be fully plated with the second plating material. In further cases, only a part of a respective second diepad 16B may be plated with the second plating material, while another part of the diepad may remain non-plated.

The second leadframes 14B may further include multiple second leads 22B which may be mechanically and/or electrically connected to an associated second diepad 16B or not. The number of second leads 22B per individual second leadframe 14B may depend on the type of the semiconductor package that is to be manufactured. In the shown case, each individual second leadframe 14B may include multiple second leads 22B arranged to the left of a respective second diepad 16B. However, in other cases, a number and arrangement of the second leads 22B for an individual second leadframe 14B may differ.

The second leads 22B may be plated with a fourth plating material which may, for example, depend on a material of the wires that may be connected to the second leads 22B. For example, the fourth plating material may include or may correspond to at least one of Cu or Ag. In one example, the fourth plating material on the second leads 22B may be different from the second plating material on the second diepads 16B. In a further example, the fourth plating material and the second plating material may be the same.

The second leadframe panel 12B may include a core onto which the second plating material of the second diepads 16B and/or the fourth plating material of the second leads 22B may have been deposited. The core of the second leadframe panel 12B may include a second core material. In particular, the second core material of the second leadframe panel 12B may differ from the first core material of the first leadframe panel 12A. For example, the second core material may include or may be made of Al or an Al-alloy.

In FIG. 2C, a plurality of first semiconductor chips 24A of a first type may be mounted on the first leadframe panel 12A. For example, the step of FIG. 2C may correspond to the step 8 of FIG. 1. In the illustrated example, the first semiconductor chips 24A may be mounted on the first diepads 16A. However, in further examples, the first semiconductor chips 24A may be mounted at least partially on the first leads 22A. In the non-limiting shown case, a single first semiconductor chip 24A may be mounted on each first diepad 16A. However, it is to be understood that the number and arrangement of the second semiconductor chips 24B may depend on the type of semiconductor package that is to be manufactured and may differ in other examples.

In general, the semiconductor chips described herein may be manufactured from an elemental semiconductor material (e.g. Si) or from a wide band gap semiconductor material or a compound semiconductor material (e.g. SiC, GaN, SiGe, GaAs). The semiconductor chips may be of arbitrary types and may include integrated circuits with active electronic components and/or passive electronic components. The integrated circuits may be designed as logic integrated circuits, analog integrated circuits, mixed signal integrated circuits, power integrated circuits, memory circuits, integrated passives, etc. Note that, throughout this description, the terms “chip”, “semiconductor chip”, “die”, “semiconductor die” may be used interchangeably.

In particular, the first semiconductor chips 24A may be power semiconductor chips. In this context, the term “power semiconductor chip” may refer to a semiconductor chip providing at least one of high voltage blocking or high current-carrying capabilities. A power semiconductor chip may be configured for high currents having a maximum current value of a few Amperes, such as e.g. 10A, or a maximum current value of up to or exceeding 100A. Similarly, voltages associated with such current values may have values of a few Volts to a few tens or hundreds or even thousands of Volts, such as e.g. about 1200V, about 1600V, about 2400V, or the like. Power semiconductor chips may be used in any kind of power application like e.g. MOSFETs (Metal Oxide Semiconductor Field Effect Transistors), half bridge circuits, power modules including a gate driver, etc. For example, power chips may include or may be part of a power device like e.g. a power MOSFET, an LV (low voltage) power MOSFET, a power IGBT (Insulated Gate Bipolar Transistor), a power diode, a superjunction power MOSFET, etc.

The first semiconductor chips 24A may be mounted on the first leadframe panel 12A based on a process or technique that may particularly be configured for mounting power semiconductor chips to a leadframe or a diepad. For example, mounting the first semiconductor chips 24A on the first leadframe panel 12A may be based on at least one of a diffusion soldering process, a soft soldering process, a preform soldering process, a sintering process or a solder paste process.

After the first semiconductor chips 24A have been mounted on the first leadframe panel 12A, further steps may be performed in the context of FIG. 2C which are not explicitly illustrated for the sake of simplicity. For example, the first semiconductor chips 24A may be electrically coupled to the first leadframe panel 12A via first electrical connection elements. More particular, the first semiconductor chips 24A may be electrically coupled to at least one of the first diepads 16A or the first leads 22A. For example, the first electrical connection elements may include or may correspond to first wires including a first wire material.

The properties of the first wires and the employed wire bonding processes may particularly be adapted to the type of the first semiconductor chips 24A and the properties of the first and third plating materials that may be arranged on the first diepads 16A and the first leads 22A, respectively. For example, the first wire material may include Al or alloys thereof. Electrically coupling the first semiconductor chips 24A to the first leadframe panel 12A via the first wires may be based on a wedge bonding process.

In FIG. 2D, a plurality of second semiconductor chips 24B of a second type different from the first type may be mounted on the second leadframe panel 12B. For example, the step of FIG. 2D may correspond to the step 10 of FIG. 1. In the illustrated example, the second semiconductor chips 24B may be mounted on the second diepads 16B. However, in further examples, the second semiconductor chips 24B may be mounted at least partially on the second leads 22B. In the non-limiting shown case, a single second semiconductor chip 24B may be mounted on each second diepad 16B. However, it is to be understood that the number and arrangement of the second semiconductor chips 24B may depend on the type of semiconductor package that is to be manufactured and may differ in other examples.

In particular, the second semiconductor chips 24B may be at least one of logic semiconductor chips or driver semiconductor chips. For example, a logic or driver semiconductor chip may be configured to e.g. drive and/or control one or more power semiconductor chips, such as via a gate terminal of a power transistor chip. Some logic semiconductor chips may thus be referred to as driver semiconductor chips (or drivers) or control semiconductor chips (or controllers). In particular, in a manufactured semiconductor package, a logic or driver semiconductor chip 24B may be configured to control or drive one or more power semiconductor chips 24A.

The second semiconductor chips 24B may be mounted on the second leadframe panel 12B based on a process or technique that may particularly be configured for mounting logic or driver semiconductor chips to a leadframe or a diepad. For example, mounting the second semiconductor chips 24B on the second leadframe panel 12B may be based on at least one of a gluing process, a die attach film process or a sintering process. In particular, since the first semiconductor chips 24A and the second semiconductor chips 24B may be of different types, mounting the first semiconductor chips 24A on the first leadframe panel 12A and mounting the second semiconductor chips 24B on the second leadframe panel 12B may be based on different processes.

After the second semiconductor chips 24B have been mounted on the second leadframe panel 12B, further steps may be performed in the context of FIG. 2D which are not explicitly illustrated for the sake of simplicity. For example, the second semiconductor chips 24B may be electrically coupled to the second leadframe panel 12B via second electrical connection elements. More particular, the second semiconductor chips 24B may be electrically coupled to at least one of the second diepads 16B or the second leads 22B. For example, the second electrical connection elements may include or may correspond to second wires including a second wire material different from the first wire material of the first wires.

The properties of the second wires and the employed wire bonding processes may particularly be adapted to the type of the second semiconductor chips 24B and the properties of the second and fourth plating materials that may be arranged on the second diepads 16B and the second leads 22B, respectively. For example, the second wire material may include Cu or alloys thereof. In addition, electrically coupling the second semiconductor chips 24B to the second leadframe panel 12B via the second wires may be based on a ball bonding process. In particular, since the first semiconductor chips 24A and the second semiconductor chips 24B may be of different types, electrically coupling the first semiconductor chips 24A to the first leadframe panel 12A via the first wires and electrically coupling the second semiconductor chips 24B to the second leadframe panel 12B via the second wires may be based on different processes.

In FIG. 2E, the first leadframe panel 12A and the second leadframe panel 12B may be mechanically connected to form a combined leadframe panel 26. For example, the step of FIG. 2E may correspond to the step 6 of FIG. 1. The leadframe panels 12A and 12B may be connected using any suitable process or technique. For example, mechanically connecting the first leadframe panel 12A and the second leadframe panel 12B to form the combined leadframe panel 26 may include at least one of clamping, gluing or welding. As can be seen from the example of FIG. 2E, in the combined leadframe panel 26, the rows of the first diepads 16A of the first leadframe panel 12A may be arranged at the second gaps 20B of the second leadframe panel 12B, and the rows of the second diepads 16B of the second leadframe panel 12B may be arranged at the first gaps 20A of the first leadframe panel 12A.

In one case, the first leadframe panel 12A and the second leadframe panel 12B may be aligned to each other such that the first peripheral frame 18A and the second peripheral frame 18B may overlap when viewed in the z-direction. After such alignment, the first peripheral frame 18A and the second peripheral frame 18B may be attached to each other based on at least one of clamping, gluing or welding. That is, a mechanical connection between the first leadframe panel 12A and the second leadframe panel 12B may solely include a mechanical connection between the first peripheral frame 18A and the second peripheral frame 18B while the first individual leadframes 14A of the first leadframe panel 12A are not necessarily connected to the second individual leadframes 14B of the second leadframe panel 12B.

In the example of FIG. 2, mounting the first semiconductor chips 24A on the first leadframe panel 12A as shown in FIG. 2C and mounting the second semiconductor chips 24B on the second leadframe panel 12B as shown in FIG. 2D may be performed before the first leadframe panel 12A and the second leadframe panel 12B are mechanically connected to form the combined leadframe 26. In such case, mounting the first semiconductor chips 24A and the second semiconductor chips 24B may be performed separately in different production lines. However, it is to be understood that in further examples the first leadframe panel 12A and second leadframe panel 12B may be connected first to form the combined leadframe panel 26, and afterwards the first semiconductor chips 24A and the second semiconductor chips 24B may be mounted at the respective positions on the combined leadframe 26.

In a similar fashion, electrically coupling the first semiconductor chips 24A to the first leadframe panel 12A via the first wires and electrically coupling the second semiconductor chips 24B to the second leadframe panel 12B via the second wires may be performed before the first leadframe panel 12A and the second leadframe panel 12B are mechanically connected to form the combined leadframe 26. In such case, electrically coupling the semiconductor chips 24A and 24B to the leadframe panels 12A and 12B, respectively, may be performed separately in different production lines. However, it is to be understood that in further examples the first leadframe panel 12A and the second leadframe panel 12B may be connected first to form the combined leadframe 26, and afterwards the first semiconductor chips 24A and the second semiconductor chips 24B may be electrically coupled to respective positions on the combined leadframe 26 via corresponding wires.

In a further optional step of FIG. 2E, at least one of the first semiconductor chips 24A may be electrically coupled to at least one of the second semiconductor chips 24B via one or multiple electrical connections elements, such as e.g. at least one of wires, ribbons, clips, or the like. In this context, at least one of a wire bonding process, a clip attachment, or the like, may be performed. In particular, an electrical coupling may be provided between first semiconductor chips 24A and second semiconductor chips 24B that will be included in a same semiconductor package that is to be manufactured. An example for such semiconductor package and an electrical connection between a first semiconductor chip 24A and a second semiconductor chip 24B is shown and discussed in connection with FIG. 4.

FIG. 2F illustrates the combined leadframe 26 of FIG. 2E when viewed in the y-direction. In the illustrated example, the two leadframe panels 12A and 12B may have different thicknesses, in particular when measured in the z-direction. In particular, a first thickness of the first leadframe panel 12A may be larger than a second thickness of the second leadframe panel 12B. For the case of the first semiconductor chips 24A being power semiconductor chips, a larger first thickness of the first leadframe panel 12A may increase heat dissipation and allow a transport of high electrical currents. A smaller second thickness of the second leadframe panel 12B may provide a finer signal routing, if the second semiconductor chips 24B correspond to logic and/or driver semiconductor chips.

FIG. 2G illustrates a cross-sectional side view of the combined leadframe 26 of FIG. 2E with respect to a sectional plane A-A′ and when viewed in the x-direction. As can be seen from the examples of FIGS. 2F and 2G, the first leadframe panel 12A and the second leadframe panel 12B (in particular the first diepads 16A and the second diepads 16B) may be arranged in the combined leadframe panel 26 at different heights with respect to the z-direction (the first leadframe panel 12A may be arranged beneath the second leadframe panel 12B). As can be further seen from FIG. 2G, due to such different heights of the leadframe panels 12A and 12B, a free or empty region or space 28 may be provided beneath the second diepads 16B of the first leadframe panel 12B, the functionality of which will be described later on.

In FIG. 2H, an encapsulation process may be performed, wherein the first semiconductor chips 24A, the second semiconductor chips 24B and the combined leadframe panel 26 may be at least partially encapsulated in an encapsulation material 30. For example, the method of FIG. 1 may be extended by the step of FIG. 2H. The encapsulation material 30 may include or may be made of at least one of an epoxy, a filled epoxy, a glass fiber filled epoxy, an imide, a thermoplast, a thermoset polymer, a polymer blend, a laminate, a mold compound, or the like. Various techniques may be used for encapsulating components in the encapsulation material 30, for example at least one of compression molding, injection molding, powder molding, liquid molding, map molding, laminating, or the like.

In the illustrated example, a plurality of bars (or strips) made of the encapsulation material 30 may be formed, wherein each bar may encapsulate one row of first diepads 16A and an adjacent row of second diepads 16B. In the shown case, the bars of encapsulation material 30 may extend in the y-direction between the peripheral frames 18A and 18B. The peripheral frames 18A and 18B may remain uncovered by the encapsulation material 30.

Referring back to the side view of FIG. 2G, after performing the encapsulation process, the bottom main surface of the first leadframe panel 12A opposite the upper main surface on which the first semiconductor chips 24A may be mounted may remain uncovered by the encapsulation material 30. Contrarily, the bottom main surface of the second leadframe panel 12B opposite the upper main surface on which the second semiconductor chips 24B may be mounted may be covered by the encapsulation material 30. In other words, the previously empty region 28 may have been filled with the encapsulation material 30. Accordingly, the second leadframe panel 12B may be electrically isolated by a dielectric encapsulation material 30. This way, a defined isolation thickness for the covered second leadframes 14B and the second semiconductor chips 24B arranged thereon may be provided by selecting a corresponding thickness of the first leadframe panel 12A.

It is to be understood that the method of FIG. 2 may include further steps which are not explicitly illustrated for the sake of simplicity. In an exemplary further step, the semiconductor chips 24A, 24B and the combined leadframe panel 26 embedded in the encapsulation material 30 may be singulated into multiple semiconductor packages. In this context, the bars of encapsulation material 30 as shown in FIG. 2H may be separated from each other by cutting or dicing the arrangement along the y-direction between the individual bars. Furthermore, each separated bar of encapsulation material 30 may be separated into multiple semiconductor packages by cutting or dicing the respective bar in the x-direction.

For example, a singulated semiconductor package may include an individual first leadframe 14A including a first diepad 16A plated with the first plating material and an individual second leadframe 14B including a second diepad 16B plated with the second plating material. A first semiconductor chip 24A of the first type may be mounted on the first leadframe 14A, and a second semiconductor chip 24B of the second type may be mounted on the second leadframe 14B. Note that a more detailed example of a semiconductor package 400 in accordance with the disclosure which may be manufactured by the methods of FIGS. 1 and 2 is shown and described later on in connection with FIG. 4.

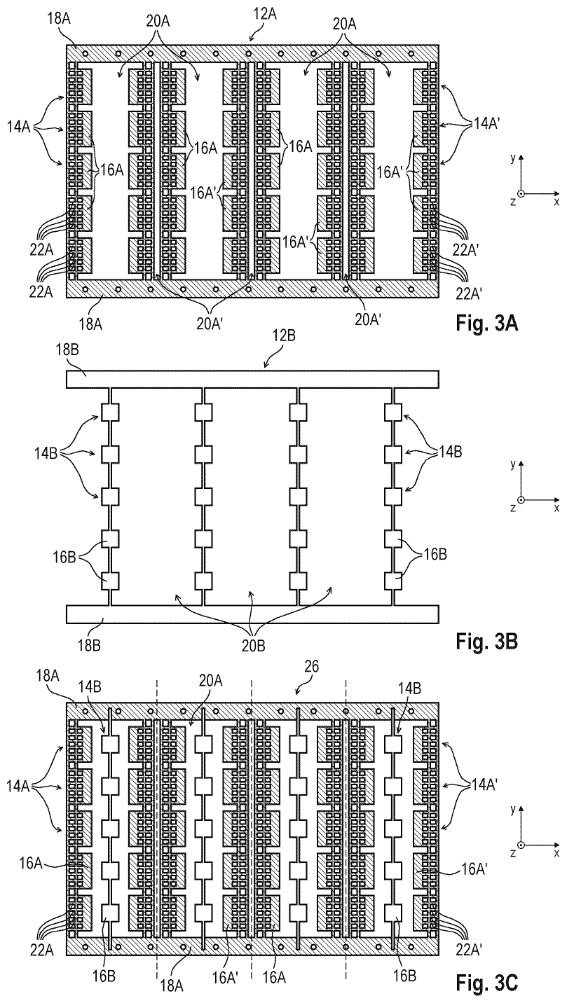

The methods of FIGS. 1 and 2 have been described based on exemplary and non-limiting types of leadframe panels 12A and 12B. However, it is to be understood that the methods may also be performed with other types of leadframe panels. In general, the design and material properties of the employed leadframe panels may depend on the type of semiconductor package that is to be manufactured by the respective method. In this context, FIGS. 3A to 3C schematically illustrate leadframe panels of an alternative design which may also be used in a method in accordance with the disclosure. The leadframe panels of FIG. 3 as described in the following may include some or all features of the leadframe panels of FIG. 2.

A first leadframe panel 12A shown in FIG. 3A may include two different types of individual first leadframes 14A and 14A′. The first type individual leadframes 14A may include multiple leads 22A and diepads 16A that may be arranged in rows connected to opposite sides of the first peripheral frame 18A. In a similar fashion, the second type individual leadframes 14A′ may include multiple leads 22A′ and diepads 16A′ that may also be arranged in rows connected to opposite sides of the first peripheral frame 18A. A row of first type diepads 16A may be separated from an adjacent row of second type diepads 16A′ to the right by a broad gap 20A. In addition, the same row of first type diepads 16A may be separated from an adjacent row of second type diepads 16A′ to the left by a narrower gap 20A′. Similar to previous examples, the first diepads 14A and 14A′ may be plated with a first plating material.

A second leadframe panel 12B shown in FIG. 3B may include only one type of individual second leadframes 14B. The individual second leadframes 14B may include multiple second diepads 16B that may be arranged in rows connected to opposite sides of the second peripheral frame 18B. In the illustrated example, the individual second leadframes 14B do not necessarily include leads. The rows of second diepads 16B may be separated by second gaps 20B. Similar to previous examples, the second diepads 16B may be plated with a second plating material different from the first plating material.

FIG. 3C shows a combined leadframe 26 which may have been formed by mechanically connecting the first leadframe panel 12A and the second leadframe panel 12B of FIGS. 3A and 3B. In the combined leadframe panel 26, the rows of the second diepads 16B of the second leadframe panel 12B may be arranged at the first gaps 20A of the first leadframe panel 12A. Similar to the example of FIG. 2, semiconductor chips may be mounted to the leadframe panels 12A and 12B and electrically coupled to the individual leadframes as previously discussed in connection with FIGS. 2C and 2D. In further steps, the semiconductor chips and the combined leadframe 26 may be encapsulated and singulated in order to obtain a plurality of semiconductor packages. In this context, a singulation process may, for example, include a cutting or dicing along the second gaps 20A′ as indicated by dashed lines in FIG. 3C. For example, a singulated semiconductor package may include one first diepad 16A of the first type, one first diepad 16A′ of the second type and one second diepad 16B.

In a more specific and non-limiting example, the combined leadframe 26 of FIG. 3C may be used for manufacturing semiconductor packages including three semiconductor chips which may be electrically interconnected to form a half bridge circuit. Here, each of the fabricated semiconductor packages may include a first power semiconductor chip and a second power semiconductor which may, for example, correspond to a low side switch and a high side switch of the half bridge circuit, respectively. The two power semiconductor chips may be mounted on first diepads 16A and 16A′ obtained from the first leadframe panel 12A. In addition, a fabricated semiconductor package may include a logic semiconductor chip which may be configured to control and/or drive at least one of the first power semiconductor chip and the second power semiconductor chip. The logic semiconductor chip may be mounted on a second diepad 16B obtained from the second leadframe panel 12B. In particular, the logic semiconductor chip may include a driver circuit configured to drive the high side switch and the low side switch of the half bridge circuit.

Referring now to FIG. 4, a cross-sectional side view of a semiconductor package 400 in accordance with the disclosure is schematically illustrated. For example, the semiconductor package 400 may be manufactured based on one of the previously described methods in accordance with the disclosure. Accordingly, previously made comments in connection with any of FIGS. 1 to 3 may also hold true for the example of FIG. 4.

The semiconductor package 400 may include a first leadframe 14A including a first diepad 16A which may be (in particular fully) plated with a first plating material 32A. For example, the first leadframe 14A (or more particular a core of the first leadframe 14A) may include or may be made of Cu or a Cu-alloy, and the first plating material 32A may include or may be made of NiNiP or Ni. In addition, the semiconductor package 400 may include a second leadframe 14B including a second diepad 16B which may be (in particular fully) plated with a second plating material 32B different from the first plating material 32A. For example, the second leadframe 14B (or more particular a core of the second leadframe 14B) may include or may be made of Cu or a Cu-alloy, and the second plating material 32B may include or may be made of Ag or Cu. In the illustrated example, possible leads of the leadframes 14A and 14B are not shown for the sake of simplicity.

A first semiconductor chip 24A of a first type may be mounted on the first leadframe 14A (or more particular on the first diepad 16A). Furthermore, a second semiconductor chip 24B of a second type different from the first type may be mounted on the second leadframe 14B (or more particular on the second diepad 16B). The first semiconductor chip 24A may include a backside metallization 34 and may be mounted on the first leadframe 14A via the backside metallization 34. The backside metallization 34 may consist of a metal stack including different metals configured to provide an appropriate electrical and/or mechanical contact between the first leadframe 14A and the first semiconductor chip 24A. For example, the backside metallization 34 may include or may correspond to at least one of a multi-layered backside metallization, a copper backside metallization, a silver backside metallization, or the like.

In a similar fashion, the second semiconductor chip 24B may be mounted on the second leadframe 14B via its backside or backside material 36. In one example, the backside material 36 of the second semiconductor chip 24B may include or may correspond to a non-metallic material, such as bare silicon, silicone oxide, or the like. In the illustrated example, the backside material 36 may be attached to the second leadframe plating 32B via a die attach material 38, such as an adhesive. In a further example, the backside material 36 may include or may correspond to a backside metallization similar to the backside metallization 34 of the first semiconductor chip 24A.

The first semiconductor chip 24A may include at least one first contact pad 42A which may be arranged on the top surface of the first semiconductor chip 24A. For example, the first contact pad 42A may include or may be made of Al (Si) Cu. In a similar fashion, the second semiconductor chip 24B may include at least one second contact pad 42B which may be arranged on the top surface of the second semiconductor chip 24B. For example, the second contact pad 42A may include or made be made of at least one of PdAu or Cu.

The semiconductor package 400 may include at least one first electrical connection element 40A electrically coupling the first semiconductor chip 24A and the first leadframe 14A. In the illustrated example, the first electrical connection element 40A may include or may correspond to a first wire 40A including a first wire material. In further examples, and depending on the considered application, the first wire 40A may be replaced by another kind of electrical connection element, such as a ribbon, clip, or the like. In particular, a first wire 40A may be in direct contact with a first contact pad 42A and the first plating material 32A of the first diepad 16A. Alternatively, or additionally, a first wire 40A may be in direct contact with a first contact pad 42A and a third plating material of a first lead (not illustrated) of the first leadframe 14A.

Furthermore, the semiconductor package 400 may include at least one second electrical connection element 40B. In the illustrated example, the second electrical connection element 40B may include or may correspond to a second wire 40B including a second wire material different from the first wire material. In further examples, and depending on the considered application, the second wire 40B may be replaced by another kind of electrical connection element, such as a ribbon, clip, or the like. For example, a second wire 40B may electrically couple the second semiconductor chip 24B and the second leadframe 14B. In particular, a second wire 40B may be in direct contact with a second contact pad 42B and the second plating material 32B of the second diepad 16B. Alternatively, or additionally, a second wire 40B may be in direct contact with a second contact pad 42B and a fourth plating material of a second lead (not illustrated) of the second leadframe 14B. In addition, a second wire 40B may electrically couple the second semiconductor chip 24B and the first semiconductor chip 24A. In particular, the second wire 40B may be in direct contact with a second contact pad 42B of the second semiconductor chip 24B and a first contact pad 42A of the first semiconductor chip 24A. It is to be noted that in further examples, and depending on the considered application, one or more of the wires 40B may be replaced by another kind of electrical connection element, such as a ribbon, clip, or the like.

It is to be understood that the components of the semiconductor package 400 may be made of different materials and may be processed based on various techniques. In this context, four exemplary scenarios are specified in the following. In each scenario, the first semiconductor chip 24A may be a power semiconductor chip and the second semiconductor chip 24B may be a driver or logic semiconductor chip.

In a first scenario, the first semiconductor chip 24A may be attached to the first leadframe 14A (or to the first diepad 16A) via its backside metallization 34 based on a diffusion soldering process. The first wire 40A may be made of Al and may be bonded based on a wedge-wedge bonding process. The first leadframe plating 32A may be NiP or Ni on the diepad 16A and on the wirebond area. The second semiconductor chip 24B may be attached to the second leadframe 14B (or to the second diepad 16B) via its silicon backside 36 using an Ag glue. The second wire 40B may be made of Cu or Au and may be bonded based on a ball bonding process. In case of an Au ball-bond, the second leadframe plating 32B may be Ag or the second leadframe 14B may be a micro pre-plated frame (uPPF). In case of a Cu ball-bond, the second leadframe plating 32B may be Cu or Ag or the second leadframe 14B may be a micro pre-plated frame (uPPF).

In a second scenario, the first semiconductor chip 24A may be attached to the first leadframe 14A (or to the first diepad 16A) via its backside metallization 34 based on a diffusion soldering process. The first wire 40A may be made of Cu and may be bonded based on a wedge-wedge bonding process. The first leadframe plating 32A may be NiP or Ni on the diepad 16A and Cu on the wirebond area. The second semiconductor chip 24B may be attached to the second leadframe 14B (or to the second diepad 16B) via its silicon backside 36 using an Ag glue. The second wire 40B may be made of Cu or Au and may be bonded based on a ball bonding process. In case of an Au ball-bond, the second leadframe plating 32B may be made of Ag or the second leadframe 14B may be a micro pre-plated frame (uPPF). In case of a Cu ball-bond, the second leadframe plating 32B may be made of Cu or Ag or the second leadframe 14B may be a micro pre-plated frame (uPPF).

In a third scenario, the first semiconductor chip 24A may be attached to the first leadframe 14A (or to the first diepad 16A) via a 4-layer-backside metallization 34 based on a solder paste process. The first wire 40A may be made of Al and may be bonded based on a wedge-wedge bonding process. The first leadframe plating 32A may be bare Cu or Ag on the diepad 16A and NiP or Ni on the wirebond area. The second semiconductor chip 24B may be attached to the second leadframe 14B (or to the second diepad 16B) via its silicon backside 36 using an Ag glue. The second wire 40B may be made of Cu or Au and may be bonded based on a ball bonding process. In case of an Au ball-bond, the second leadframe plating 32B may be made of Ag or the second leadframe 14B may be a micro pre-plated frame (uPPF). In case of a Cu ball-bond, the second leadframe plating 32B may be made of Cu or Ag or the second leadframe 14B may be a micro pre-plated frame (uPPF).

In a fourth scenario, the first semiconductor chip 24A may be attached to the first leadframe 14A (or to the first diepad 16A) via a 4-layer-backside metallization 34 based on a solder paste process. The first wire 40A may be made of Cu and may be bonded based on a wedge-wedge bonding process. The first leadframe plating 32A may be Cu or Ag on the diepad 16A and the wirebond area. The second semiconductor chip 24B may be attached to the second leadframe 14B (or to the second diepad 16B) via its silicon backside 36 using an Ag glue. The second wire 40B may be made of Cu or Au and may be bonded based on a ball bonding process. In case of an Au ball-bond, the second leadframe plating 32B may be made of Ag or the second leadframe 14B may be a micro pre-plated frame (uPPF). In case of a Cu ball-bond, the second leadframe plating 32B may be made of Cu or Ag or the second leadframe 14B may be a micro pre-plated frame (uPPF).

The concepts in accordance with the disclosure described herein may outperform conventional concepts in different ways as described in the following. In this regard, the following comments are not to be regarded as conclusive.

The concepts described herein may provide the use of leadframes having different thicknesses in a same semiconductor package. In particular, no cost-intensive processes (such as selective etching) are required in this regard. The possibility of a semiconductor package having a thick leadframe for power semiconductor chips and a thin leadframe for logic or driver semiconductor chips may be beneficial for realizing SIPs (Systems in a Package). In this regard, the thick leadframe may provide heat dissipation and a proper transport of high electrical currents, while the thin leadframe may provide a fine signal routing.

The concepts described herein may provide semiconductor packages including exposed diepads and non-exposed diepads having a defined isolation thickness. In this regard, complex and cost-intensive isolation concepts (such as TIM sheets, foils) are not necessarily required.

The concepts described herein may provide cost-efficient methods for using different leadframes and different plating materials in a same semiconductor package. For example, a first leadframe may be a copper leadframe having a first plating material, while a second leadframe may be an aluminum leadframe having a second plating material different from the first plating material.

The concepts described herein may provide a cost-efficient integration of various semiconductor chips in a same package using leadframes having different plating materials. In particular, each of the included leadframes can be produced as fully plated leadframe so that no spot plating may be required. The presented concepts do not necessarily require expensive plating technologies (such as spot plating) which may strongly increase overall package costs.

### Examples

In the following, methods and semiconductor packages in accordance with the disclosure are described by means of examples.

Example 1 is a method, comprising: providing a first leadframe panel comprising multiple first leadframes, wherein the first leadframes comprise multiple first diepads plated with a first plating material; providing a second leadframe panel separate from the first leadframe panel and comprising multiple second leadframes, wherein the second leadframes comprise multiple second diepads plated with a second plating material different from the first plating material; mechanically connecting the first leadframe panel and the second leadframe panel to form a combined leadframe panel; mounting a plurality of first semiconductor chips of a first type on the first leadframe panel; and mounting a plurality of second semiconductor chips of a second type different from the first type on the second leadframe panel.

Example 2 is a method according to Example 1, wherein: the first leadframes further comprise multiple first leads plated with a third plating material, and/or the second leadframes further comprise multiple second leads plated with a fourth plating material.

Example 3 is a method according to Example 2, wherein: the third plating material is different from the first plating material, and/or the fourth plating material is different from the second plating material.

Example 4 is a method according to Example 2, wherein: the first plating material and the third plating material are the same, and/or the second plating material and the fourth plating material are the same.

Example 5 is a method according to one of the preceding Examples, wherein: the first diepads are fully plated with the first plating material, and the second diepads are fully plated with the second plating material.

Example 6 is a method according to one of the preceding Examples, wherein: the first plating material comprises at least one of Ni, NiP, NiNiP, Cu, Ag, and the second plating material comprises at least one of Cu, Ag and/or the second leadframe panel is a pre-plated frame (PPF) or a micro pre-plated frame (uPPF).

Example 7 is a method according to one of the preceding Examples, wherein: the first semiconductor chips are power semiconductor chips, and the second semiconductor chips are at least one of logic semiconductor chips or driver semiconductor chips.

Example 8 is a method according to one of the preceding Examples, wherein: the first leadframe panel has a first thickness, and the second leadframe panel has a second thickness smaller than the first thickness.

Example 9 is a method according to one of the preceding Examples, wherein mounting the first semiconductor chips on the first leadframe panel and mounting the second semiconductor chips on the second leadframe panel are based on different processes.

Example 10 is a method according to one of the preceding Examples, wherein: mounting the first semiconductor chips on the first leadframe panel is based on at least one of a diffusion soldering process, a soft soldering process, a preform soldering process, a sintering process or a solder paste process, and mounting the second semiconductor chips on the second leadframe panel is based on at least one of a gluing process, a die attach film process, a soldering process, a soft soldering process or a sintering process.

Example 11 is a method according to one of the preceding Examples, wherein: mounting the first semiconductor chips on the first leadframe panel and mounting the second semiconductor chips on the second leadframe panel are performed before the first leadframe panel and the second leadframe panel are mechanically connected.

Example 12 is a method according to one of the preceding Examples, wherein: mounting the first semiconductor chips on the first leadframe panel and mounting the second semiconductor chips on the second leadframe panel are performed in different production lines.

Example 13 is a method according to one of the preceding Examples, wherein: the first leadframe panel comprises a first peripheral frame and multiple rows of the first diepads, wherein the rows of the first diepads are connected to opposite sides of the first peripheral frame and separated by first gaps, the second leadframe panel comprises a second peripheral frame and multiple rows of the second diepads, wherein the rows of the second diepads are connected to opposite sides of the second peripheral frame and separated by second gaps, and in the combined leadframe panel the rows of the first diepads of the first leadframe panel are arranged at the second gaps of the second leadframe panel and the rows of the second diepads of the second leadframe panel are arranged at the first gaps of the first leadframe panel.

Example 14 is a method according to one of the preceding Examples, wherein the first diepads and the second diepads are arranged at different heights in the combined leadframe panel.

Example 15 is a method according to one of the preceding Examples, further comprising: performing an encapsulation process, wherein the first semiconductor chips, the second semiconductor chips and the combined leadframe panel are at least partially encapsulated in an encapsulation material, and singulating the encapsulated semiconductor chips and the combined leadframe panel into multiple semiconductor packages.

Example 16 is a method according to Example 15, wherein: a singulated semiconductor package comprises a first leadframe comprising a first diepad plated with the first plating material and a second leadframe comprising a second diepad plated with the second plating material; a first semiconductor chip of the first type is mounted on the first leadframe; and a second semiconductor chip of the second type is mounted on the second leadframe.

Example 17 is a method according to Example 15 or 16, wherein: the first semiconductor chips are mounted on a first main surface of the first leadframe panel, the second semiconductor chips are mounted on a second main surface of the second leadframe panel, and after performing the encapsulation process a main surface of the first leadframe panel opposite the first main surface is uncovered by the encapsulation material and a main surface of the second leadframe panel opposite the second main surface is covered by the encapsulation material.

Example 18 is a method according to one of the preceding Examples, further comprising: electrically coupling the first semiconductor chips to the first leadframe panel via first electrical connection elements comprising a first electrical connection element material, and electrically coupling the second semiconductor chips to the second leadframe panel via second electrical connection elements comprising a second electrical connection element material different from the first electrical connection element material.

Example 19 is a method according to Example 18, wherein: the first electrical connection elements comprise first wires comprising a first wire material, and the second electrical connection elements comprise second wires comprising a second wire material.

Example 20 is a method according to Example 19, wherein: the first electrical connection element material comprises Al, and the second electrical connection element material comprises Cu.

Example 21 is a method according to Example 19 or 20, wherein electrically coupling the first semiconductor chips to the first leadframe panel via the first electrical connection elements and electrically coupling the second semiconductor chips to the second leadframe panel via the second electrical connection elements are based on different processes.

Example 22 is a method according to one of Examples 19 to 21, wherein: electrically coupling the first semiconductor chips to the first leadframe panel via the first electrical connection elements is based on a wedge bonding process, and electrically coupling the second semiconductor chips to the second leadframe panel via the second electrical connection elements is based on a ball bonding process.

Example 23 is a method according to one of the preceding Examples, wherein mechanically connecting the first leadframe panel and the second leadframe panel to form the combined leadframe panel comprises at least one of clamping, gluing or welding.

Example 24 is a method according to one of the preceding Examples, wherein: a core of the first leadframe panel comprises a first core material, and a core of the second leadframe panel comprises a second core material different from the first core material.

Example 25 is a method according to Example 24, wherein: the first core material comprises Cu, and the second core material comprises Al.

Example 26 is a semiconductor package, comprising: a first leadframe comprising a first diepad plated with a first plating material; a second leadframe comprising a second diepad plated with a second plating material different from the first plating material; a first semiconductor chip of a first type mounted on the first leadframe; and a second semiconductor chip of a second type different from the first type mounted on the second leadframe.

Example 27 is a semiconductor package according to Example 26, wherein: the first semiconductor chip comprises a backside metallization and is mounted on the first leadframe via the backside metallization, and the second semiconductor chip is mounted on the second leadframe via its backside formed by a non-metallic material.

Example 28 is a semiconductor package according to Example 26 or 27, wherein: the first semiconductor chip is a power semiconductor chip, and the second semiconductor chip is at least one of a logic semiconductor chip or a driver semiconductor chip.

Example 29 is a semiconductor package according to one of Examples 26 to 28, further comprising: a first electrical connection element comprising a first electrical connection element material and electrically coupling the first semiconductor chip and the first leadframe; and a second electrical connection element comprising a second electrical connection element material different from the first electrical connection element material and electrically coupling the second semiconductor chip and the second leadframe.

Example 30 is a semiconductor package according to Example 29, wherein: the first electrical connection element comprises a first wire comprising a first wire material, and the second electrical connection element comprises a second wire comprising a second wire material.

Example 31 is a semiconductor package according to one of Examples 26 to 30, wherein: the first diepad is fully plated with the first plating material, and the second diepad is fully plated with the second plating material.

As employed in this description, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the words “over” and “on” used with regard to e.g. a material layer formed or located “over” or “on” a surface of an object may be used herein to mean that the material layer may be located (e.g. formed, deposited, etc.) “directly on”, e.g. in direct contact with, the implied surface. The words “over” and “on” used with regard to e.g. a material layer formed or located “over” or “on” a surface may also be used herein to mean that the material layer may be located (e.g. formed, deposited, etc.) “indirectly on” the implied surface with e.g. one or more additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the previous instances. In addition, the articles “a” and “an” as used in this application and the appended claims may generally be construed to mean “one or more” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include a step of providing the component in a suitable manner, even if such step is not explicitly described or illustrated in the figures.

Although the disclosure has been shown and described with respect to one or more implementations, equivalent alterations and modifications will occur to others skilled in the art based at least in part upon a reading and understanding of this description and the annexed drawings. The disclosure includes all such modifications and alterations and is limited only by the concept of the following claims. In particular regard to the various functions performed by the above described components (e.g., elements, resources, etc.) the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application.

1. A method, comprising:
providing a first leadframe panel comprising multiple first leadframes, wherein the first leadframes comprise multiple first diepads plated with a first plating material;
providing a second leadframe panel separate from the first leadframe panel and comprising multiple second leadframes, wherein the second leadframes comprise multiple second diepads plated with a second plating material different from the first plating material;
mechanically connecting the first leadframe panel and the second leadframe panel to form a combined leadframe panel;
mounting a plurality of first semiconductor chips of a first type on the first leadframe panel; and
mounting a plurality of second semiconductor chips of a second type different from the first type on the second leadframe panel.

2. The method of claim 1, wherein:
the first leadframes further comprise multiple first leads plated with a third plating material, and/or
the second leadframes further comprise multiple second leads plated with a fourth plating material.

3. The method of claim 2, wherein:
the third plating material is different from the first plating material, and/or
the fourth plating material is different from the second plating material.

4. The method of claim 2, wherein:
the first plating material and the third plating material are the same, and/or
the second plating material and the fourth plating material are the same.

5. The method of claim 1, wherein:
the first diepads are fully plated with the first plating material, and
the second diepads are fully plated with the second plating material.

6. The method of claim 1, wherein:
the first plating material comprises at least one of Ni, NiP, NiNiP, Cu, Ag, and
the second plating material comprises at least one of Cu, Ag and/or the second leadframe panel is a pre-plated frame or a micro pre-plated frame.

7. The method of claim 1, wherein:
the first semiconductor chips are power semiconductor chips, and
the second semiconductor chips are at least one of logic semiconductor chips or driver semiconductor chips.

8. The method of claim 1, wherein:
the first leadframe panel has a first thickness, and
the second leadframe panel has a second thickness smaller than the first thickness.

9. The method of claim 1, wherein mounting the first semiconductor chips on the first leadframe panel and mounting the second semiconductor chips on the second leadframe panel are based on different processes.

10. The method of claim 1, wherein:
mounting the first semiconductor chips on the first leadframe panel is based on at least one of a diffusion soldering process, a soft soldering process, a preform soldering process, a sintering process or a solder paste process, and
mounting the second semiconductor chips on the second leadframe panel is based on at least one of a gluing process, a die attach film process, a soldering process, a soft soldering process or a sintering process.

11. The method of claim 1, wherein:
mounting the first semiconductor chips on the first leadframe panel and mounting the second semiconductor chips on the second leadframe panel are performed before the first leadframe panel and the second leadframe panel are mechanically connected.

12. The method of claim 1, wherein:
mounting the first semiconductor chips on the first leadframe panel and mounting the second semiconductor chips on the second leadframe panel are performed in different production lines.

13. The method of claim 1, wherein:
the first leadframe panel comprises a first peripheral frame and multiple rows of the first diepads, wherein the rows of the first diepads are connected to opposite sides of the first peripheral frame and separated by first gaps,
the second leadframe panel comprises a second peripheral frame and multiple rows of the second diepads, wherein the rows of the second diepads are connected to opposite sides of the second peripheral frame and separated by second gaps, and
in the combined leadframe panel the rows of the first diepads of the first leadframe panel are arranged at the second gaps of the second leadframe panel and the rows of the second diepads of the second leadframe panel are arranged at the first gaps of the first leadframe panel.

14. The method of claim 1, wherein the first diepads and the second diepads are arranged at different heights in the combined leadframe panel.

15. The method of claim 1, further comprising:
performing an encapsulation process, wherein the first semiconductor chips, the second semiconductor chips and the combined leadframe panel are at least partially encapsulated in an encapsulation material, and
singulating the encapsulated semiconductor chips and the combined leadframe panel into multiple semiconductor packages.

16. The method of claim 15, wherein:
a singulated semiconductor package comprises a first leadframe comprising a first diepad plated with the first plating material and a second leadframe comprising a second diepad plated with the second plating material;
a first semiconductor chip of the first type is mounted on the first leadframe; and
a second semiconductor chip of the second type is mounted on the second leadframe.

17. The method of claim 15, wherein:
the first semiconductor chips are mounted on a first main surface of the first leadframe panel,
the second semiconductor chips are mounted on a second main surface of the second leadframe panel, and
after performing the encapsulation process a main surface of the first leadframe panel opposite the first main surface is uncovered by the encapsulation material and a main surface of the second leadframe panel opposite the second main surface is covered by the encapsulation material.

18. The method of claim 1, further comprising:
electrically coupling the first semiconductor chips to the first leadframe panel via first electrical connection elements comprising a first electrical connection element material, and
electrically coupling the second semiconductor chips to the second leadframe panel via second electrical connection elements comprising a second electrical connection element material different from the first electrical connection element material.

19. The method of claim 18, wherein:
the first electrical connection elements comprise first wires comprising a first wire material, and
the second electrical connection elements comprise second wires comprising a second wire material.

20. The method of claim 19, wherein:
the first electrical connection element material comprises Al, and
the second electrical connection element material comprises Cu.

21. The method of claim 19, wherein electrically coupling the first semiconductor chips to the first leadframe panel via the first electrical connection elements and electrically coupling the second semiconductor chips to the second leadframe panel via the second electrical connection elements are based on different processes.

22. The method of claim 19, wherein:
electrically coupling the first semiconductor chips to the first leadframe panel via the first electrical connection elements is based on a wedge bonding process, and
electrically coupling the second semiconductor chips to the second leadframe panel via the second electrical connection elements is based on a ball bonding process.

23. The method of claim 1, wherein mechanically connecting the first leadframe panel and the second leadframe panel to form the combined leadframe panel comprises at least one of clamping, gluing or welding.

24. The method of claim 1, wherein:
a core of the first leadframe panel comprises a first core material, and
a core of the second leadframe panel comprises a second core material different from the first core material.

25. The method of claim 24, wherein:
the first core material comprises Cu, and
the second core material comprises Al.

26. A semiconductor package, comprising:
a first leadframe comprising a first diepad plated with a first plating material;
a second leadframe comprising a second diepad plated with a second plating material different from the first plating material;
a first semiconductor chip of a first type mounted on the first leadframe; and
a second semiconductor chip of a second type different from the first type mounted on the second leadframe.

27. The semiconductor package of claim 26, wherein:
the first semiconductor chip comprises a backside metallization and is mounted on the first leadframe via the backside metallization, and
the second semiconductor chip is mounted on the second leadframe via its backside formed by a non-metallic material.

28. The semiconductor package of claim 26, wherein:
the first semiconductor chip is a power semiconductor chip, and
the second semiconductor chip is at least one of a logic semiconductor chip or a driver semiconductor chip.

29. The semiconductor package of claim 26, further comprising:
a first electrical connection element comprising a first electrical connection element material and electrically coupling the first semiconductor chip and the first leadframe; and
a second electrical connection element comprising a second electrical connection element material different from the first electrical connection element material and electrically coupling the second semiconductor chip and the second leadframe.

30. The semiconductor package of claim 29, wherein:
the first electrical connection element comprises a first wire comprising a first wire material, and
the second electrical connection element comprises a second wire comprising a second wire material.

31. The semiconductor package of claim 26, wherein:
the first diepad is fully plated with the first plating material, and
the second diepad is fully plated with the second plating material.
